(19) United States
(12) Patent Application Publication
(10) Pub. No.: US 2017/0156000 A1
(43) Pub. Date: Jun. 1, 2017

(54) Vehicle with ear piece to provide audio safety

(71) Applicant: BRAGI GmbH, Munchen (DE)

(72) Inventor: Peter Vincent Boesen, Munchen (DE)

(21) Appl. No.: 15/356,909

(22) Filed: Nov. 21, 2016

Related U.S. Application Data
(60) Provisional application No. 62/260,439, filed on Nov. 27, 2015.

(51) Int. Cl. H04R 1/10; H03G 3/30; H04R 29/00

(52) U.S. Cl. CPC H04R 1/1083; H04R 29/001; H04R 1/1016; H04R 1/1041; H03G 3/3005; H04R 2499/13; H04R 2420/07

(57) ABSTRACT

An earpiece includes an earpiece housing, a speaker associated with the ear piece housing, a microphone associated with the ear piece housing a wireless transceiver disposed within the ear piece housing and a processor disposed within the ear piece housing. The earpiece is configured to connect with a vehicle using the wireless transceiver and after connection with the vehicle automatically enter a driving mode. In the driving mode, the earpiece senses ambient sound with the microphone and reproduces the ambient sound at the speaker.

### PRIORITY STATEMENT

This application claims priority to U.S. Provisional Patent Application 62/260,439, filed on Nov. 27, 2015, and entitled Vehicle with ear piece to provide audio safety, hereby incorporated by reference in its entirety.

### FIELD OF THE INVENTION

The present invention relates to vehicles, and wearable devices. More particularly, but not exclusively, the present invention relates to ear pieces used in vehicles.

### BACKGROUND

Vehicles may come with various types of electronics packages. These packages may be standard or optional and include electronics associated with communications or entertainment. However, there are various problems and deficiencies with such offerings. What is needed are vehicles with improved electronics options which create, improve, or enhance safety and overall experience of vehicles. In particular, what is needed are vehicles which integrate with wearable devices.

### SUMMARY

Therefore, it is a primary object, feature, or advantage of the present invention to improve over the state of the art.

It is another object, feature, or advantage of the present invention to communicate between vehicle systems and wearable devices.

It is a further object, feature, or advantage of the present invention to use wearable devices to increase safety in vehicles.

It is another object, feature, or advantage of the present invention to enhance an existing vehicle through addition of a wearable device.

One or more of these and/or other objects, features, or advantages of the present invention will become apparent from the specification and claims that follow. No single embodiment need provide each and every object, feature, or advantage. Different embodiments to may have different objects, features, or advantages. Therefore, the present invention is not to be limited to or by any objects, features, or advantages stated herein.

According to one aspect, an earpiece includes an earpiece housing, a speaker associated with the ear piece housing, a microphone associated with the ear piece housing a wireless transceiver disposed within the ear piece housing and a processor or other intelligent control system disposed within the ear piece housing. The earpiece is configured to connect with a vehicle using the wireless transceiver and after connection with the vehicle automatically enter a driving mode. In the driving mode, the earpiece senses ambient sound with the microphone and reproduces the ambient sound at the speaker. The ear piece may provide for persistently maintaining the driving mode while a user of the earpiece is driving the vehicle. The earpiece may be locked in the driving mode while a user of the earpiece is driving the vehicle. The earpiece is further configured to receive audio from one or more microphones of the vehicle. One or more of the microphones of the vehicle may be outside of a vehicle cabin of the vehicle. One or more of the microphones of the vehicle may be within a vehicle cabin of the vehicle. The processor or other intelligent control system may be adapted to process the ambient sound to remove noise. The processor or other intelligent control system may be adapted to combine the ambient sound and an audio stream. The processor or other intelligent control system may be adapted to reduce the amplitude of the ambient sound and/or to increase the amplitude of the ambient sound or portions thereof.

According to another aspect, a system includes a set of earpieces comprising at least one of a left ear piece and a right ear piece, each of the earpieces comprising an ear piece housing, a speaker, a microphone, a processor or other intelligent control system operatively connected to the microphone and the speaker, and a transceiver disposed within the ear piece housing and operatively connected to the processor or other intelligent control system, wherein the processor or other intelligent control system is configured to provide a driving mode wherein in the driving mode ambient sound sensed with the microphone of the ear piece is reproduced at the speaker of the ear piece. The system further includes a vehicle in operative communication with the ear piece and wherein the vehicle is configured to set the driving mode of each of the set of ear pieces. Each of the ear pieces may be configured to receive audio from one or more microphones of the vehicle. One of the microphones of the vehicle may be outside of a vehicle cabin of the vehicle. One of the microphones of the vehicle may be within a vehicle cabin of the vehicle. The processor or other intelligent control system may be adapted to process the ambient sound to remove noise. The processor or other intelligent control system may be adapted to is combine the ambient sound and an audio stream. The audio stream may be from an entertainment system of the vehicle. The processor or other intelligent control system may be adapted to reduce or increase amplitude of the ambient sound or portions thereof.

According to another aspect a method includes providing an earpiece comprising an ear piece housing, a speaker, a microphone, a processor or other intelligent control system operatively connected to the microphone and the speaker, and a transceiver disposed within the ear piece housing and operatively connected to the processor or other intelligent control system. The method further includes communicating data from a vehicle to the earpiece to put the earpiece in a driving mode. In the driving mode the ambient sound sensed with the microphone of die ear piece is reproduced at the speaker of the ear piece. The method may further include providing the vehicle, the vehicle comprising a vehicle transceiver for operative communication with the transceiver of the ear piece. The method may further include communicating an audio stream from the vehicle to the ear piece. The method may further include combining the audio stream from the vehicle with the ambient sound at the ear piece. The method may further include receiving audio from one or more vehicle microphones and communicating an audio stream containing the audio from the vehicle to the earpiece. At least one of the vehicle microphones may be within a vehicle cabin of the vehicle. At least one of the vehicle microphones may be outside of the vehicle cabin of the vehicle. The processing of the ambient sound at the ear piece may be used to change audio characteristics of the ambient sound. The audio characteristics may include the amplitude or volume of the ambient sound and the processing may include increasing or decreasing the volume of the ambient sound or portions thereof.

### BRIEF DESCRIPTION OF THE DRAWINGS

FIG. 1 illustrates one example of use of a wearable device in conjunction with a vehicle.

FIG. 2 illustrates a wearable device in the form of a set of ear pieces.

FIG. 3 is a block diagram illustrating a device.

FIG. 4 illustrates ear pieces in operative communication with modules or systems of a vehicle over a vehicle network.

FIG. 5 illustrates the transfer of data including audio streams or vehicle state information from a vehicle to a wearable device.

FIG. 6 illustrates a method.

### DETAILED DESCRIPTION

Some of the most important factors in selecting a vehicle such as car may be the technology available to enhance the experience. This may be of particular importance in certain vehicle segments such as for luxury vehicles. Another important factor in selecting a vehicle ma be the available safety features. According to various aspects, the present invention allows for wearable devices including ear pieces to enhance the experience of vehicles and according to some aspects, the present invention allows for wearable devices such as earpieces to enhance the overall safety of the vehicle. Therefore, it is expected that the technology described herein will make any vehicle so equipped more desirable to customers, more satisfying to customers, and potentially more profitable for the vehicle manufacturer. Similarly at least some of the various aspects may be added to existing vehicles as after-market accessories to improve the safety or experience of existing vehicles.

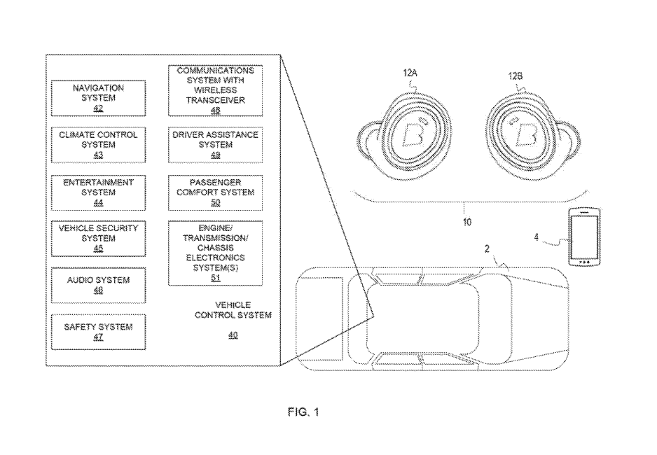

FIG. 1 illustrates one example of use of a wearable device in conjunction with a vehicle. As shown in FIG. 1 there is a vehicle 2. Although the vehicle shown is a full-size sedan, it is contemplated that the vehicle may be of any number of types of cars, trucks, sport utility vehicles, vans, mini-vans, automotive vehicles, commercial vehicles, agricultural vehicles, construction vehicles, specialty vehicles, recreational vehicles, buses, motorcycles, aircraft, boats, ships, yachts, spacecraft, or other types of vehicles. The vehicle may be gas-powered, diesel powered, electric, solar-powered, or human-powered. The vehicle may be actively operated by a driver or may be partially or completely autonomous or self-driving. The vehicle 2 may have a vehicle control system 40. The vehicle control system is a system which my include any number of mechanical and electromechanical subsystems. As shown in FIG. 1, such systems may include a navigation system 42, an entertainment system 44, a vehicle security system 45, an audio system 46, a safety system 47, a communications system 48 preferably with a wireless transceiver, a driver assistance system 49, a passenger comfort system 50, and an engine/transmission, chassis electronics system(s) 51. Of course, other examples of vehicle control sub-systems are contemplated. In addition, it is to be understood that there may be overlap between some of these different vehicle systems and the presence or absence of these vehicle systems as well as other vehicle systems may depend upon the type of vehicle, the type of fuel or propulsion system, the size of the vehicle, and other factors and variables. In the automotive context, examples of the driver assistance system 49 may include one or more subsystems such as a lane assist system, a speed assist system, a blind spot detection system, a park assist system, and an adaptive cruise control system. In the automotive context, examples of the passenger comfort system 50 may include one or more subsystems such as automatic climate control, electronic seat adjustment, automatic wipers, automatic headlamps, and automatic cooling. In the automotive context, examples of the safety system 47 may include active safety systems such as air bags, hill descent control, and an emergency brake assist system. Aspects of the navigation system 42, the entertainment system 44, the audio system 46, and the communications system 48 may be combined into an infotainment system.

One or more wearable devices such as a set of earpieces 10 including a left earpiece 12A and a right earpiece 12B may in operative communication with the vehicle control system 40 such as through the communication system 48. For example, the communication system 48 may provide a Bluetooth or BLE link to wearable devices or may otherwise provide for communications with the wearable devices preferably through wireless communications. The vehicle 2 may communicate with the wearable device(s) directly, or alternatively, or in addition, the vehicle 2 may communicate with the wearable device(s) through an intermediary device such as a mobile device 4 which may be a mobile phone, a tablet, or other type of mobile device.

As will be explained in further details with respect to various examples, the wearable device(s) 10 interact with the vehicle control system 40 in any number of different ways. For example, the wearable device(s) 10 may provide sensor data, identity information, stored information, streamed information, or other types of information to the vehicle. Based on this information, the vehicle may take any number of actions which may include one or more actions taken by the vehicle control system (or subsystems thereof). In addition, the vehicle 2 may communicate sensor data, identity information, stored information, streamed information or other types of information to the wearable device(s) 10.

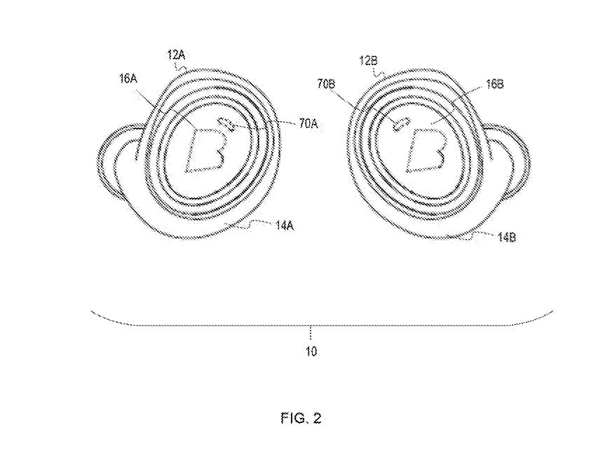

FIG. 2 illustrates one example of a wearable device in the form of a set of ear pieces 10 in greater detail. FIG. 1 illustrates a set of earpiece wearables 10 which includes a left earpiece 12A and a right earpiece 12B. Each of the earpieces wearables 12A, 12B has an earpiece wearable housing 14A, 14B which may be in the form of a protective shell or casing and may be an in-the-ear earpiece housing. A left infrared through ultraviolet spectrometer 16A and right infrared through ultraviolet spectrometer 16B is also shown. Each earpiece 12A, 12B may include one or more microphones 70A, 70B. Note that the air microphones 70A, 70B are outward facing such that the air microphones 70A, 70B may capture ambient environmental sound. It is to be understood that any number of microphones may be present including air conduction microphones, hone conduction microphones, or other audio sensors.

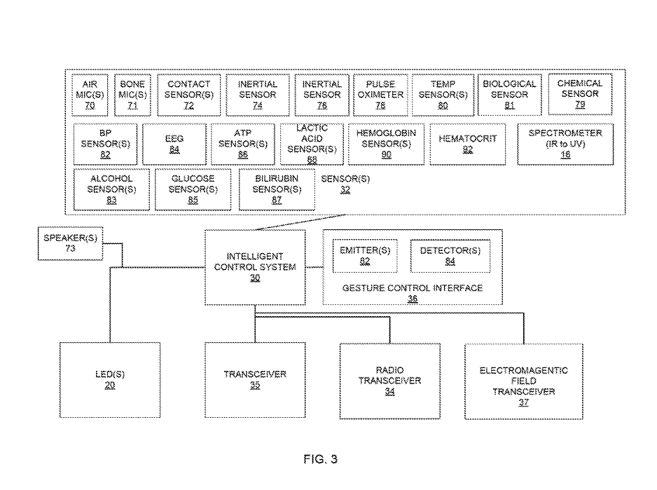

FIG. 3 is a block diagram illustrating a device. The device may include one or more LEDs 20 electrically connected to an intelligent control system 30. The intelligent control system 30 may include one or more processors, microcontrollers, application specific integrated circuits, or other types of integrated circuits. The intelligent control system 30 may also be electrically connected to one or more sensors 32. Where the device is an earpiece, the sensor(s) may include an inertial sensor 74, another inertial sensor 76. Each inertial sensor 74, 76 may include an accelerometer, a gyro sensor or gyrometer, a magnetometer or other type of inertial sensor. The sensor(s) 32 may also include one or more contact sensors 72, one or more bone conduction microphones 71, one or more air conduction microphones 70, one or more chemical sensors 79, a pulse oximeter 76, a temperature sensor 80, or other physiological or biological sensor(s). Further examples of physiological or biological sensors include an alcohol sensor 83, glucose sensor 85, or bilirubin sensor 87. Other examples of physiological or biological sensors may also be included in the device. These may include a blood pressure sensor 82, an electroencephalogram (EEG) 84, an Adenosine Triphosphate (ATP) sensor, a lactic acid sensor 88, a hemoglobin sensor 90, a hematocrit sensor 92 or other biological or chemical sensor. A spectrometer 16 is also shown. The spectrometer 16 may he an infrared (IR) through ultraviolet (UV) spectrometer although it is contemplated that any number of wavelengths in the infrared, visible, or ultraviolet spectrums may he detected. The spectrometer 16 is preferably adapted to measure environmental wavelengths for analysis and recommendations and thus preferably is located on or at the external facing side of the device.

A gesture control interface 36 is also operatively connected to or integrated into the intelligent control system 30. The gesture control interface 36 may include one or more emitters 82 and one or more detectors 84 for sensing user gestures. The emitters may be of any number of types including infrared LEDs. The device may include a transceiver 35 which may allow for induction transmissions such as through near field, magnetic induction. A short range transceiver 34 using Bluetooth, BLE, UWB, or other means of radio communication may also be present. The short range transceiver 34 may be used to communicate with the vehicle control system. In operation, the intelligent control system 30 may he configured to convey different information using one or more of the LED(s) 20 based on context or mode of operation of the device. The various sensors 32, the intelligent control system 30, and other electronic components may be located on the printed circuit board of the device. One or more speakers 73 may also be operatively connected to the intelligent control system 30.

An electromagnetic (E/M) field transceiver 37 or other type of electromagnetic field receiver is also operatively connected to the intelligent control system 30 to link the intelligent control system r 30 to the electromagnetic field of the user. The use of the E/M transceiver 37 allows the device to link electromagnetically into a personal area network or body area network or other device.

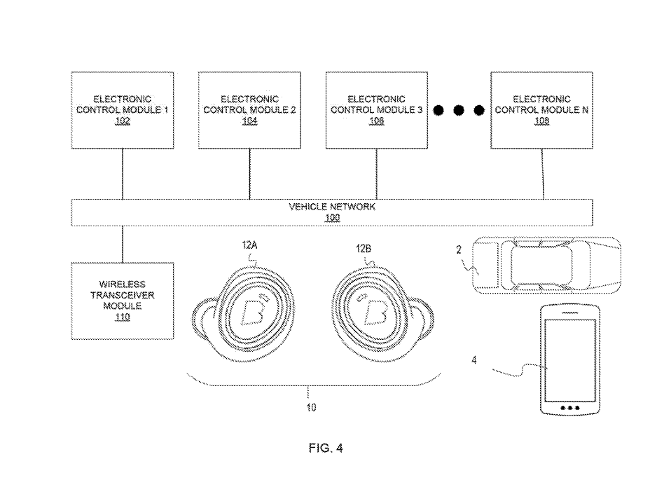

FIG. 4 illustrates another example of one or more wearable ear pieces in operative communication with a vehicle. In FIG. 4, a vehicle network 100 is shown. According to one aspect, the wearable devices 12A, 12B may communicate information through a vehicle network 100 associated with a vehicle 2. Data, instructions, commands, or audio streams may be communicated over the vehicle network 100 or vehicle bus to and from the wearable devices.

Protocols which are used may include a Controller Area Network (CAN), Local interconnect Network (LIN), or others including proprietary network protocols or network protocol overlays.

Various types of electronic control modules 102, 104, 106, 108 or electronic control units may communicate over the network 100 of the vehicle. These may include electronic modules such as an engine control unit (ECU), a transmission control unit (TCU), an anti-lock braking system (ABS), a body control module (BCM), a door control unit (DCU), an electric power steering control unit (PSCU), a human-machine interface (HMI), powertrain control module (PCM), speed control unit (SCU), telematic control unit (TCU), brake control unit (BCM), battery management system, entertainment system and numerous others. Any number of electronic control modules may be operatively connected to the vehicle network 100.

In one embodiment a wireless transceiver module 110 is operatively connected to a vehicle network 100 and it is the wireless transceiver module 110 which is in operative communication with one or more wearable devices such as wearable ear piece 12A, 12B. Once the wearable ear pieces 12A, 12B have communicated with the vehicle (such as through the wireless transceiver module 110), the ear piece may enter a driver mode. In the driver mode or driving mode the wearable ear pieces 12A, 12B provide for audio pass-through by reproducing audio detected with one or more microphones of the device at one or more speakers of the device. Thus, even though the driver is wearing ear pieces, the driver is still able to bear ambient sounds. In addition, this audio may be combined with other audio streams being produced at the ear pieces.

It is generally accepted as dangerous for individuals operating a vehicle to wear head phones, ear buds, or other such devices which prevent individuals from being able to hear ambient sounds when operating vehicles and generally is prohibited by laws for motor vehicles. According to one aspect, a wearable device is in the form of a set of earpieces. The earpieces are configured to capture and reproduce ambient sounds to the operator. This may be accomplished by using one or more microphones on the earpieces to detect ambient sound and then to re-create the ambient sound at one or more speakers of the earpiece. Thus, even though the operator is wearing earpieces there is audio transparency.

Where the driver is wearing earpieces the earpieces may lock themselves in a mode such as a driver or driving which provides for ambient noise pass-through. Thus, even though the driver is wearing ear pieces the driver can hear ambient sound. In addition, the earpiece may provide for further processing in order to enhance ambient sounds to assist the driver in operating the vehicle. This enhancement may be performed in various ways including increasing the volume or amplitude of particular audio signals. This enhancement may also provide for removing background noise or decreasing the volume of background noise or decreasing the amplitude or volume of the ambient sounds. For example, where the vehicle is a construction vehicle operating in a noisy environment, the earpieces may be configured for decreasing the amplitude or volume of the ambient sounds thus serving to protect the user from the noisy environment yet still allowing the user to hear the ambient sounds for safety reasons.

It is further contemplated that in addition to one or more microphones on the earpiece itself one or more additional audio streams may be sent to the earpieces from one or more microphones associated with the vehicle. These microphones may be positioned within the cabin of the vehicle or may be positioned at the exterior of the vehicle so as to pick up external noises. It is further contemplated that the earpieces and the vehicle may provide for intelligently determining when to reproduce particular audio streams. For example, when the driver shifts the vehicle into reverse, an audio stream from a microphone at the rear of the vehicle may be reproduced at the earpieces. Thus, for example, if a child or animal is playing behind the vehicle or near the vehicle the driver may be alerted to their presence by the associated sound and avoid a potential accident. Similarly, when the driver begins to shift lanes or signals a right turn or a left audio streams from the microphones of the vehicle may be reproduced at the earpiece to provide audio cues regarding the presence or absences of other vehicles to help avoid a potential accident. Or alternatively, when a driver performs particular actions as detected by the vehicle particular ambient noises may be amplified or otherwise emphasized.

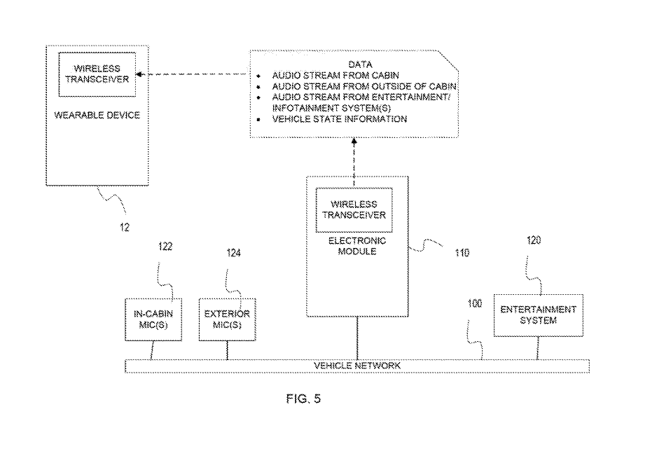

One or more audio streams from an entertainment system of the vehicle or other vehicle system may also be combined with the ambient sound. It is contemplated that the one or more audio streams may be paused, muted or the volume significantly reduced based on vehicle operations. Thus, for example, when the driver begins to shift lanes the audio stream may be paused, muted, or the volume may be reduced. Similarly, if the driver begins to back up the audio stream may be paused, muted, or the volume may be reduced. Thus, as shown in FIG. 5, different information regarding vehicle state may be communicated to the wireless transceiver module 110 and to the wearable ear piece 12 after tine transceiver module 110 connects with one or more of the ear pieces 12. In addition, one or more audio streams from the vehicle may be communicated to the ear pieces 10 such as audio streams from one or more in-cabin microphones 122, one or more exterior microphones 124, or the entertainment system 120. The ear pieces 10 may then use this information to control or alter audio processing in a context appropriate manner. This may include increasing volume of a particular stream, decreasing volume of a particular stream, pausing, muting, or stopping a particular stream. In addition based on vehicle state, an additional audio stream may be communicated to the wearable device 12. The additional audio stream may include the playing an audio message associated with a vehicle function or alert condition, or other audio stream.

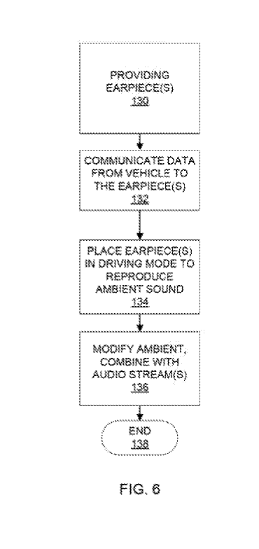

FIG. 6 illustrates one example of a method. As shown in FIG. 6, in step 130 one or more ear pieces are provided. In step 132 data is communicated from the vehicle to the ear pieces. In addition, data from the ear pieces may be communicated to the vehicle. Once the ear pieces are connected with the vehicle in step 134 the ear pieces are placed in a driving mode to reproduce ambient sound. In step 136, the ambient sound may be modified such as by combining with one or more audio streams. In step 138 the process ends.

Where ambient audio is reproduced directly or modified after processing safety can be enhanced by use of ear pieces over the use of ear pieces which do not reproduce ambient sound and even over the non-use of ear pieces. Various methods, system, and apparatus have been shown and described relating to vehicles with wearable integration or communication. The present invention is not to be limited to these specific examples but contemplates any number of related methods, system, and apparatus and these examples may vary based on the specific type of vehicle, the specific type of wearable device, and other considerations.

1. An earpiece comprising:
an earpiece housing;
a speaker associated with the ear piece housing;
a microphone associated with the ear piece housing;
a wireless transceiver disposed within the ear piece housing;
an intelligent control system disposed within the ear piece housing;
wherein the earpiece is configured to connect with a vehicle using the wireless transceiver and after connection with the vehicle automatically enter a driving mode;
wherein in the driving mode, the earpiece senses ambient sound with the microphone and reproduces the ambient sound at the speaker.

2. The earpiece of claim 1 wherein the earpiece persistently maintains the driving mode while a user of the earpiece is driving the vehicle.

3. The earpiece of claim 1 wherein the earpiece is locked in the driving mode while a user of the earpiece is driving the vehicle.

4. The earpiece of claim 1 wherein the earpiece is further configured to receive audio from one or more microphones of the vehicle.

5. The earpiece of claim 3 wherein one of the microphones of the vehicle is outside of a vehicle cabin of the vehicle.

6. The earpiece of claim 3 wherein one of the microphones of the vehicle is within a vehicle cabin of the vehicle.

7. The earpiece of claim 1 wherein the intelligent control system is adapted to process the ambient sound to remove noise.

8. The earpiece of claim 1 wherein the intelligent control system is adapted to combine the ambient sound and an audio stream.

9. The earpiece of claim 1 wherein the intelligent control system is adapted to reduce the amplitude of the ambient sound.

10. The earpiece of claim 1 wherein the intelligent control system is adapted to increase the amplitude of the ambient sound or portions thereof.

11. A method comprising:
providing an earpiece comprising an ear piece housing, a speaker, a microphone, an intelligent control system operatively connected to the microphone and the speaker, and a transceiver disposed within the ear piece housing and operatively connected to the intelligent control system;
communicating data from a vehicle to the earpiece to put the earpiece in a driving mode. wherein in the driving mode ambient sound sensed with the microphone of the ear piece is reproduced at the speaker of the ear piece.

12. The method of claim 11 further comprising providing the vehicle, the vehicle comprising a vehicle transceiver for operative communication with the transceiver of the ear piece.

13. The method of claim 11 further comprising communicating an audio stream from the vehicle to the ear piece.

14. The method of claim 13 further comprising combining the audio stream from the vehicle with the ambient sound at the ear piece.

15. The method of claim 11 further comprising receiving audio from one or more vehicle microphones and communicating an audio stream containing the audio from the vehicle to the earpiece.

16. The method of claim 15 wherein at least one of the vehicle microphones is within a vehicle cabin of the vehicle.

17. The method of claim 15 wherein at least one of the vehicle microphones is outside of the vehicle cabin of the vehicle.

18. The method of claim 11 further comprising processing the ambient sound at the ear piece to change audio characteristics of the ambient sound.

19. The method of claim 18 wherein the audio characteristics of the ambient sound include volume of the ambient sound.

20. The method of claim 19 wherein the processing comprises increasing the volume of the ambient sound.
